(19) United States
(12) Patent Application Publication
(10) Pub. No.: US 2006/0231901 A1
(43) Pub. Date: Oct. 19, 2006

(54) Semiconductor device

(75) Inventor: Daping Chu, Cambridge (GB)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 10/537,809

(22) PCT Filed: Jul. 8, 2004
(86) PCT No.: PCT/GB04/02972

§ 371 Date: Jun. 7, 2005

(30) Foreign Application Priority Data
Jul. 8, 2003 (GB) 0315982.9

(51) Int. Cl. H01L 29/94

(52) U.S. Cl. 257/369

(57) ABSTRACT

A semiconductor device comprising an n-channel region and a p-channel region formed on a common substrate, both channel regions having a source and a drain, the device further comprising a gate electrode common to both channel regions and spaced from the substrate by an area of non-polarising dielectric material arranged under the gate electrode.

The present invention relates to semiconductor devices, and in particular to semiconductor devices of a novel architecture which can be implemented as devices with a reduced device size. The present invention also relates to methods of operating such devices.

One form of semiconductor device which, advantageously, can be implemented using the present invention is an inverter. An inverter is a circuit element which is in widespread use, particularly in logic applications. Such a circuit normally consists of two individual and complementary transistors, one n-channel and one p-channel transistor (such as MOS-FETs). Inverters may be configured with a variety of combinations for the arrangement of the transistor terminals. A common configuration is to have the gate terminals of the two individual transistors joined together, with the source terminal of one transistor connected to the drain terminal of the other transistor. A typical logic circuit application may typically include in excess of one thousand inverter circuits so the space occupied on the chip by these circuits can be significant.

The increase of device density in Large Scale Integration (LSI) or Ultra Large Scale Integration(ULSI) gives rise to an increasing need for a reduction of device size. Significant resources have been expended, both in research for new device structures and device production techniques, to achieve this goal, but reduction in device size remains as an ongoing requirement.

The present invention seeks to provide a new form of semiconductor device which, in essence, can be used as two transistors and which is readily suited for large scale integration techniques. Furthermore, the device can, advantageously, be readily implemented as an inverter, enabling a significant (typically in excess of 50%) reduction in device size in comparison to known configurations of inverters because the device only requires to occupy the space of a conventional single field effect transistor (FET). Of further advantage is that the fabrication of the device of the present invention involves only conventional and well proven semiconductor manufacturing processes and techniques so it is easy to integrate.

According to a first aspect of the present invention there is provided a semiconductor device comprising an n-channel region and a p-channel region formed on a common substrate, both channel regions having a source and a drain, the device further comprising a gate electrode common to both channel regions and spaced from the substrate by an area of non-polarising dielectric material arranged under the gate electrode.

Advantageously, the source of one channel region is serially coupled with the drain of the other channel region to provide a device for functioning as an inverter.

In an alternative embodiment, the substrate comprises a thin film substrate material and, preferably, the thin film substrate material is supported on a transparent supporting material.

According to a second aspect of the present invention, there is provided a method of operating a semiconductor device according to the first aspect, the method comprising selecting a voltage applied to the gate electrode so as to selectively switch one of the channel regions between a non-conducting and a conducting condition independently of the other channel region.

According to an additional aspect of the present invention, there is provided a method of operating a semiconductor device according to the first aspect, when the substrate comprises a thin film substrate, comprising operating one of the channel regions as a thin film region and coupling the source and drain regions of the other channel region to a bias voltage, thereby to alleviate the kink effect in the said one channel region.

According to a further aspect of the present invention, there is provided a method of operating a semiconductor device according to the first aspect, when the substrate comprises a thin film substrate material supported on a transparent supporting material, comprising operating one of the channel regions as a thin film region, thereby to operate the device as a light emitting device.

Embodiments of the present invention will now be described by way of further example only and with reference to the accompanying drawings, in which:

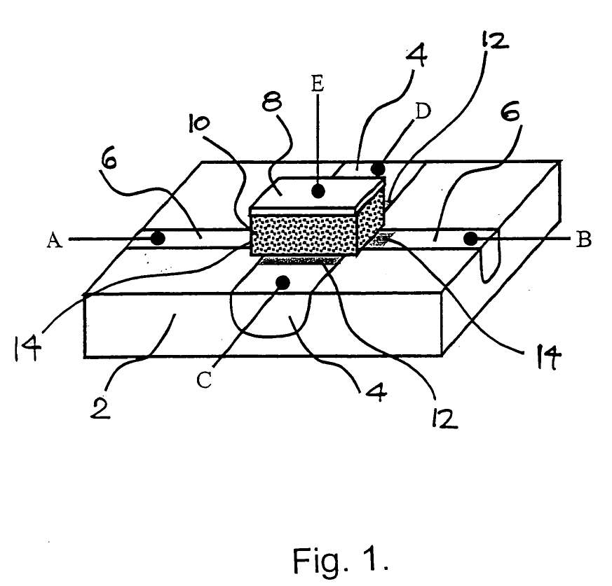

FIG. 1 shows a semiconductor device in accordance with the present invention;

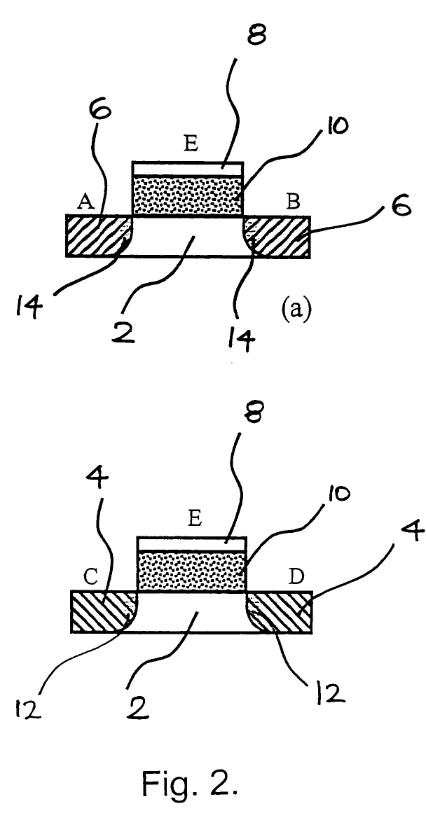

FIGS. 2(a) and 2(b) show cross sections along, respectively, the p- and n- doping directions of the device illustrated in FIG. 1, when the substrate is a thin film and the doping thickness is at least equal to the substrate depth;

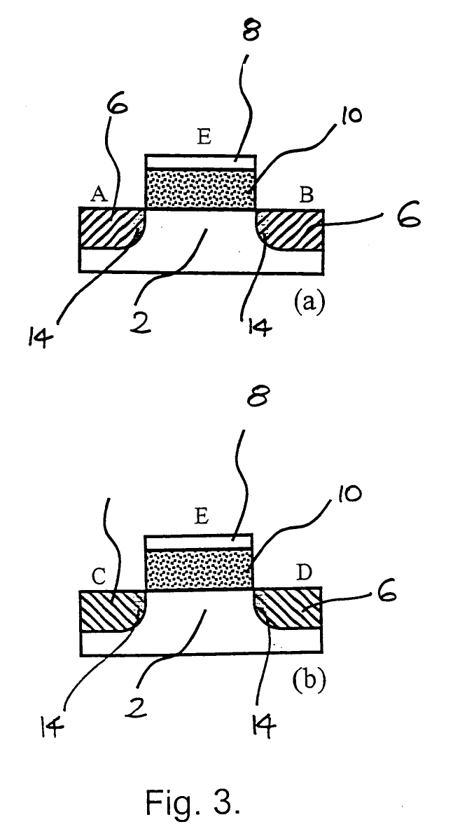

FIGS. 3(a) and 3(b) show cross sections along, respectively, the p- and n- doping directions of the device illustrated in FIG. 1, when the doping thickness is less than the substrate depth;

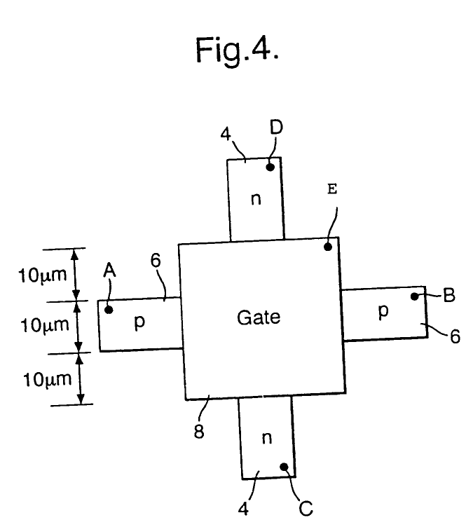

FIG. 4 shows a schematic plan view of the device illustrated in FIG. 1, with typical dimensions for the gate electrode and p- and n-channels;

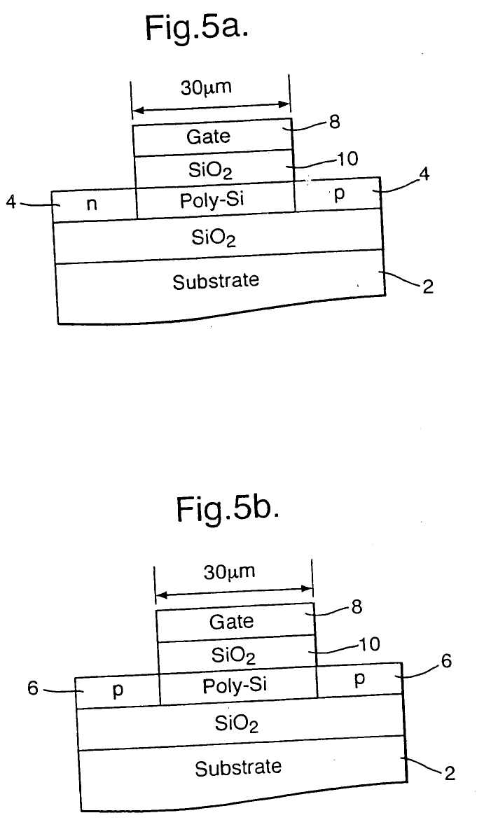

FIGS. 5(a) and 5(b) are schematic cross-sectional views in, respectively, the n- and p-channel directions of the device illustrated in FIG. 4;

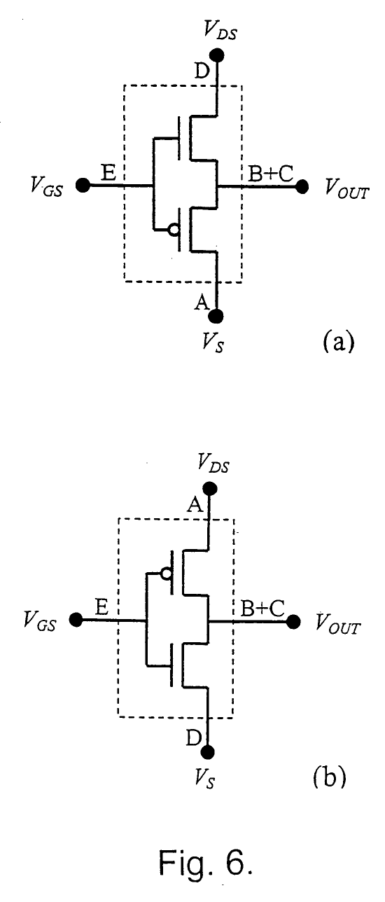

FIGS. 6(a) and 6(b) show two configurations of an inverter when the source and drain of the n-channel and p-channel transistors shown in FIG. 1 are connected in series;

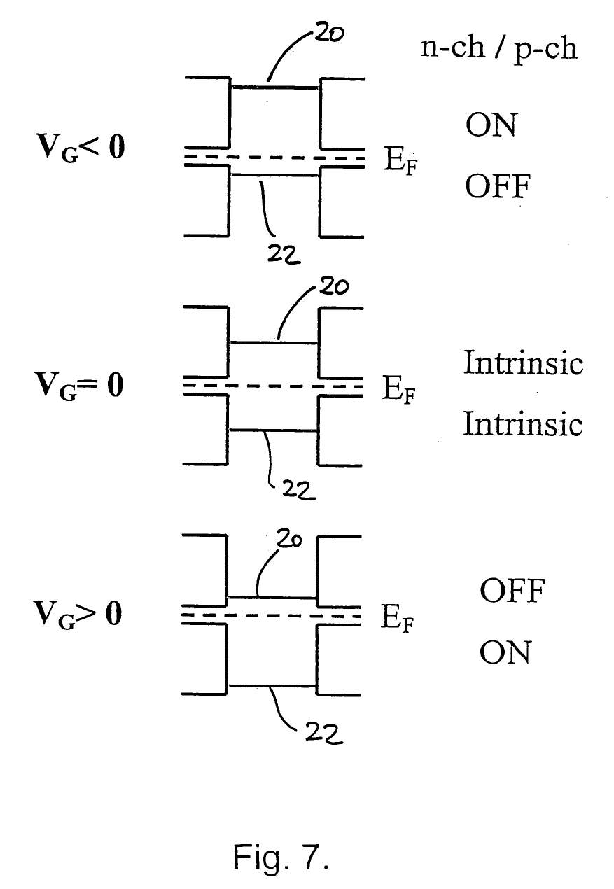

FIG. 7(a) to 79c) illustrate the working principle of the device shown in FIG. 1, in terms of band diagrams;

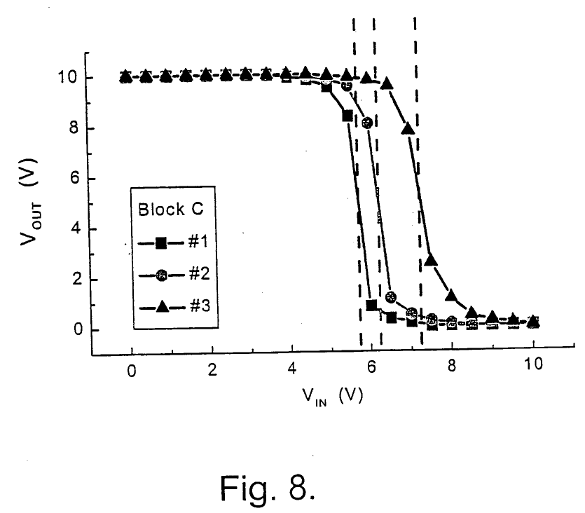

FIG. 8 shows the DC characteristics for the device illustrated in FIG. 4; and

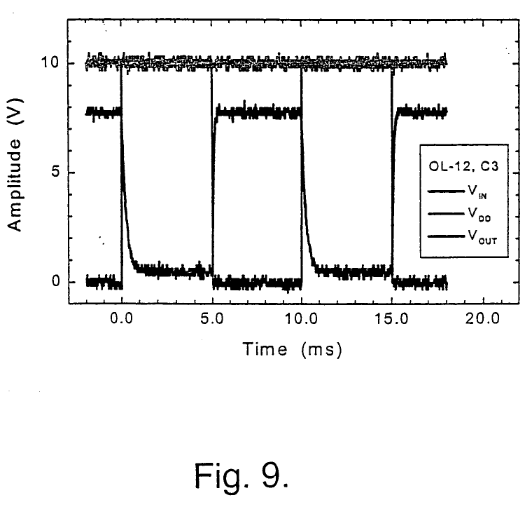

FIG. 9 shows the AC characteristics for the device illustrated in FIG. 4.

An example of a semiconductor device according to the present invention can be seen from FIG. 1. The device comprises a substrate 2 in which an n-type doped region 4 and a p-type doped region 6 are formed. The doped regions may be formed by any suitable fabrication process known in this art, such as doping through masks defining the desired positions of the doped regions. In the device shown in FIG. 1, the n- and p-type regions are shown lying substantially orthogonal to each other but it should be appreciated that alternative non-orthogonal layouts can be used, so long as a cross-over point between the n- and p-type doped regions is maintained.

A gate electrode 8 is provided above the cross-over point of the n- and p-type doped regions and this gate electrode is spaced from the substrate 2, and thus the doped regions 4 and 6, by a region of non-polarising dielectric material 10. Terminals A, B, C, D and E are provided on the n- and p-type doped regions, and the gate electrode 8, as shown in FIG. 1, to which appropriate lead wires can be coupled to the device.

Also, as shown in FIG. 1, the device may, optionally, be provided with lightly doped regions 12, 14 in, respectively, the n- and p-type doped regions 4 and 6.

FIGS. 2(a) and 2(b) show, respectively, cross-sectional views of the device along the p- and n-doping directions, and in this embodiment, which relates to a thin film transistor (TFT) configuration, the substrate 2 is in the form of a thin film having a thickness less than the doping depth. FIGS. 3(a) and 3(b) also show cross-sectional views of the device along the p- and n-doping directions but in this embodiment the substrate thickness is greater than the doping depth, such as in a silicon-on-insulator (SOI) configuration.

It can be seen from FIGS. 2 and 3 that the device comprises in each of the n- and p-channel directions, a field effect transistor (FET) structure, and these two structures share the common gate electrode 8.

It is pointed out that the n- and p-type doping regions are formed in the substrate 2 in the embodiments shown in FIGS. 2 and 3. However, the FET structure may also be formed as an organic thin film transistor structure, in which case the n- and p-type channels could be formed on the surface of the substrate 2 by a suitable process, such as by depositing organic polymers using an inkjet technique.

An example of a practical realisation for the device shown in FIG. 1 is illustrated in FIGS. 4 and 5. FIG. 4 shows a plan view of the device with the n- and p-type doping regions each being of 10 μm width with the gate electrode of square form having a side dimension of 30 μm. Hence, in this realisation of the device, the n- and p-type doping regions have the same width, i.e., a ratio of 1:1, and the gate electrode 8 has a width which is three times that of the n- and p-type regions, i.e., a ratio of 3:1.

For the n-type transistor of the device, the channel width is provided by the spacing between the p-type doping regions and the channel length is provided by the spacing between the n-type doping regions. Likewise, for the p-type transistor of the device, the channel width is provided by the spacing between the n-type doping regions, and the channel length is provided by the spacing between the p-type doping regions. Hence, in the embodiment shown in FIGS. 4 and 5, the n- and p-type transistors each has a channel width (W) to length (L), ratio (W/L) of 1:1. However, by appropriate control of the width of the n- and p-type doping regions during device fabrication, different channel width to length ratios may be provided for the transistors.

Similarly, the gate electrode 8 can be fabricated at a different ratio to that shown in FIG. 4, and need not necessarily be of square shape. Furthermore, the size of the gate electrode can be selected relative to one or both of the channel regions.

Cross-sections of the device shown in FIG. 4 in the n-type and p-type doping directions are shown in FIG. 5. The device may typically comprise a layer of silicon dioxide (SiO₂) formed on the substrate 2. A polysilicon layer is then formed on the SiO₂ layer. The dielectric region 10 is the provided by depositing a further layer of SiO₂ and a conductive layer, which are then patterned to expose the polysilicon layer. The n- and p-type doping regions are then provided in the exposed polysilicon layer by doping through appropriate masks.

An inverter, which as stated above is a circuit configuration in very common use in logic applications, consists of an n-type transistor and a p-type transistor, typically with the gates of the two transistors coupled together and the source of one transistor serially coupled to the drain of the other transistor. The semiconductor device shown in FIG. 1, in essence consists of and n-type transistor and a p-type transistor with a common gate electrode. Hence, the gate electrodes of the two transistors of the device are coupled together by virtue of the intrinsic device structure; i.e. the common gate electrode. Therefore, if the source of one transistor of the device shown in FIG. 1 is coupled to the drain of the other transistor, to connect the transistors in series, the device can function as an inverter. Two configurations of an inverter, with the serial coupling of the transistors, are shown in FIGS. 6(a) and 6(b), with the supply coupled to the terminals A and D, the inverter input coupled to the terminal E (common gate electrode 8) and the inverter output being obtained by coupling terminals B and C.

FIGS. 7(a) to 7(c) show the working principle of the inverter illustrated in FIG. 6. If the voltage at the gate electrode 8 is less than 0 volts, as shown in FIG. 7A, the energy level 20 in the p-type region is moved to a higher energy band relative to the Fermi level E_{F}, whilst the energy level 22 in the n-type region is moved to a lower energy band relative to the Fermi level. Hence, the p-type channel is turned ON and the n-type channel is held OFF.

When the voltage at the gate electrode 8 is zero, the carriers in the n- and p-type regions occupy the valance band and thus the n- and p-type channels act as intrinsic material. Hence, both the n- and p-type channels are OFF, as shown in FIG. 7(b).

When the voltage at the gate electrode 8 is greater than 0 volts, the energy level 10 in the p-type channel is moved to a lower energy band and the energy level 22 in the n-type channel is moved to a higher energy band. Hence, the n-type channel is turned ON and the p-type channel is held OFF.

Typical DC and AC characteristics for the device shown in FIGS. 4 and 5 are shown in FIGS. 8 and 9, and it will be appreciated by the skilled person in this art that these are typical characteristics for a FET. Hence, it can be seen that although the n- and p-type doping regions share a common channel region on the substrate under the gate electrode, they operate as individual transistors.

Thus, it can be seen that the present invention provides a new type of device which, in essence, consists of an n- and a p-type transistor sharing a common gate electrode. Therefore, in comparison to individual transistors, the device is small in size; typically less than half the footprint size of two individual transistors. Furthermore, the device is easy to integrate into circuit layouts using conventional semiconductor fabrication techniques.

Additionally, because of the layout of the device which provides a common area for both the n-channel and the p-channel operation, the threshold voltage shift ΔVₜₕ, will be the same for both channels; i.e. for both the n-type and the p-type transistor devices.

In the case of independent n-channel and p-channel devices, the total variance of threshold voltage, ΔVₜₕ can be expressed as:
ΔVₜₕ²_{, comb}=ΔVₜₕ²_{, n-ch}+ΔVₜₕ²_{, p-ch}

With the device of the present invention:
ΔV_{th, n-ch}=ΔV_{th, p-ch}=ΔVₜₕ

and the total variance is, therefore,
ΔVₜₕ²_{, single device}=ΔVₜₕ²=ΔVₜₕ²_{, comb}/2

Such a reduction in threshold voltage shift can advantageously be used to counter the negative effects of threshold voltage variance and therefore provide improved device performance in practical applications, particularly in TFT configurations where the threshold voltage variation is known to be particularly problematical for inverter circuits.

The device architecture also provides a way to minimise the “kink effect”, which is known to manifest particularly in n-channel transistors fabricated using silicon-on-insulator (SOI) and/or polysilicon thin film transistor (TFT) techniques.

This can be achieved by using the n-doped regions 4 and the gate terminal 8 as an n-channel field effect transistor and, at the same time, using the p-doped regions 6 under suitable bias applied to the terminals A and B, to remove the holes generated by impact ionisation near to the drain region of the configured n-channel FET, thereby reducing the “kink effect”.

Because the device is an n-type and a p-type transistor sharing a common control area under the gate electrode, both electrons and holes co-exist in this central area. These electrons and holes can recombine in this central area so the device can function as a light emitting device. In this instance, direct band gap materials may advantageously be used for the substrate material. Furthermore, a transparent support layer can be provided under the substrate material, or a transparent dielectric material 10 and transparent gate electrode 8 to allow the emission of the generated light.

Furthermore, it is known that n-channel devices conduct more readily than p-channel devices. Hence, the device of the invention may also be operated using different levels of gate voltage to selectively switch ON and OFF the n-channel and p-channel transistors.

The aforegoing description has been given by way of example only and it will be appreciated by a person skilled in the art that modifications can be made without departing from the scope of the present invention. For example, different substrate materials can be used, other than those described above, including inorganic and organic materials in any of amorphous, polycrystalline and crystalline forms.

Specific examples of modifications are as follows:

The gate dielectric material may be formed of an organic dielectric material.

The gate conductive material may be formed of an organic conductive material.

The source and drain contacts may be formed of an organic conductive material.

The semiconductor material may be formed of a magnetic type material.

The gate dielectric material may be formed of a magnetic type material.

The source and drain contacts may be formed of a magnetic type material.

A layer of ferroelectric material may be provided underneath the thin film substrate material, with an electrical contact on the other side.

A layer of magnetic material may be provided underneath the thin film substrate material, which can be magnetized by an device nearby or by an external device.

1. A semiconductor device comprising an n-channel region and a p-channel region formed on a common substrate, both channel regions having a source and a drain, the device further comprising a gate electrode common to both channel regions and spaced from the substrate by an area of non-polarising dielectric material arranged under the gate electrode.

2. A semiconductor device according to claim 1 wherein at least one of the length and/or the width of one of the channel regions differs from that of the other channel region.

3. A semiconductor device according to claim 1 wherein the gate electrode is dimensioned to have a specified ratio relative to the width and length of one of the channel regions.

4. A semiconductor device according to claim 1 wherein at least one of the n-channel and the p-channel regions has a further region, arranged between either the source and/or drain regions and the channel region, having a doping concentration less than that of the source and/or drain region.

5. A semiconductor device according to claim 1 wherein an area of the substrate which separates the n-type source and n-type drain of the n-channel region, and the p-type source and p-type drain of the p-channel region has intrinsic doping only.

6. A semiconductor device according to claim 1 wherein at least one of the n-channel and p-channel regions comprises a thin film region.

7. A semiconductor device according to claim 6 wherein the thin film region comprises an organic semiconductor material.

8. A semiconductor device according to claim 1 wherein the substrate comprises a thin film substrate material.

9. A semiconductor device according to claim 8 wherein the thin film substrate material comprises a direct band gap material.

10. A semiconductor device according to claim 8 wherein the thin film substrate material is supported on a transparent supporting material.

11. A semiconductor device according to claim 8, wherein the gate electrode and the non-polarising dielectric material comprise transparent materials.

12. A semiconductor device according to claim 1 wherein the substrate has a thickness arranged to enable the n-channel region and p-channel region under the gate to electrode function as fully or partially depleted regions.

13. A semiconductor device according to claim 1 wherein the source of one region is serially coupled with the drain of the other region to provide a device for functioning as an inverter.

14. A method of operating a semiconductor device according to claim 1 comprising selecting a voltage applied to the gate electrode so as to selectively switch one of the channel regions between a non-conducting and a conducting condition independently of the other channel region.

15. A method of operating a semiconductor device according to claim 8 comprising operating one of the channel regions as a thin film region and coupling the source and drain regions of the other channel region to a bias voltage, thereby to alleviate the kink effect in the said one channel region.

16. A method of operating a semiconductor device according to claim 10 as a light emitting device.

17. A semiconductor device according to claim 10 wherein the semiconductor device is a light emitting device.
